(19) United States
(12) Patent Application Publication
(10) Pub. No.: US 2023/0187181 A1
(43) Pub. Date: Jun. 15, 2023

(54) PLASMA-ENHANCED THIN-FILM-DEPOSITION EQUIPMENT

(71) Applicant: SKY TECH INC., Hsinchu County (TW)

(72) Inventor: JING-CHENG LIN, Hsinchu County (TW)

(21) Appl. No.: 17/552,208

(22) Filed: Dec. 15, 2021

(51) Int. Cl. H01J 37/32; C23C 16/458; C23C 16/455; C23C 16/509

(52) U.S. Cl. CPC H01J 37/32458; H01J 37/3244; H01J 37/32972; C23C 16/4583; C23C 16/45565; C23C 16/45536; C23C 16/509; H01J 2237/332

(57) ABSTRACT

A plasma-enhanced thin-film-deposition equipment includes a chamber, a carrier, a showerhead, an annular isolator and a radio-frequency coil. The chamber includes a containing space, the carrier is disposed within the containing space and provided with a carrying surface for carrying at least one substrate. The showerhead is fluidly connected to the containing space, and the showerhead is provided with a plurality of gas-outlets facing the carrying surface. The annular isolator is provided with a mounting space, and the carrier, the showerhead and the annular isolator define a reacting space, wherein the mounting space is isolated from the reacting space. The showerhead is configured to distribute a precursor into the reacting space, and the radio-frequency coil is disposed within the mounting space and coupled to a radio-frequency power supply, so as to enhance a plasma of the precursor for a thin-film-deposition process.

### TECHNICAL FIELD

The present disclosure relates to a thin-film-deposition equipment, more particularly to a plasma-enhanced thin-film-deposition equipment including an annular isolator, which is mounted with a radio-frequency coil (RF coil) and isolates the RF coil from a reacting space defined between a showerhead, a substrate carrier and the annular isolator.

### BACKGROUND

Plasma-enhanced atomic-layer deposition (PEALD) is a commonly employed technology in modern days, for manufacturing integral circuits, light-emitting diodes and displays, etc. The PEALD technology applies plasma to facilitate depositing thin film(s) on a wafer in an efficient and/or evenly distributed manner, so as to avoid overheating to a pyrolysis temperature of precursor, or a temperature that may damage the wafer.

Moreover, in order to prevent the plasma from directly contacting and causing damage to the wafer, another type of plasma reactor so called remote-plasma reactor is presented to achieve so. However, for this remote-plasma type technology, the plasma has to pass through long and deep gas-outlets of a gas-distributing showerhead to finally arrive a reacting space for the deposition process, which may cause energy loss, decay to the plasma, and hence to have an undesired result of the thin-film-deposition process.

### SUMMARY

To overcome the abovementioned drawback, as the energy-loss, decay problems of the plasma occur when passing through the showerhead, the present disclosure provides a novel plasma-enhanced thin-film-deposition equipment (PETFD equipment). The PETFD equipment includes an annular isolator, a showerhead and a carrier arranged to define a reacting space therebetween. Moreover, the annular isolator is mounted with a radio-frequency coil (RF coil), and also isolates the RF coil from the reacting space, so as to create and/or enhance the plasma, in order to improve the deposition process.

An object of the present disclosure is to provide a PETFD equipment, which includes a chamber, a carrier, a showerhead, an annular isolator and an RF coil. the chamber includes a containing space for containing a wafer. The carrier, the showerhead and the annular isolator together define a reacting space within the containing space. The annular isolator is provided with a mounting space for mounting the RF coil, and the mounting space is isolated from the containing space. The showerhead is configured to distribute at least one precursor into the reacting space. The RF coil is disposed within the mounting space, and is coupled to a radio-frequency power supply (RF power supply), thereby to prevent pollution between the containing space and the mounting space with the RF coil.

In practical use, the chamber includes a containing space for containing the carrier. The carrier is provided with a carrying surface for carrying at least one substrate. The showerhead is fluidly connected to the containing space, and is provided with a plurality of gas-outlets of the showerhead facing the carrying surface of the carrier. The PETFD equipment further includes at least one gas-inlet pipeline passing through a lid cover of the chamber, for transferring a gas into the mounting space of the annular isolator. Thereby, it is able to change and adjust condition of the gas within the mounting space of the annular isolator, according to different requirements of the deposition process. Moreover, the annular isolator is provided with an opening, for the mounting space to be fluidly connected an outside environment.

Optionally, the annular isolator is a single ring made of ceramic, metal oxide or metal nitride, thereby to seamlessly prevent the pollution between the reacting space and the mounting space with the RF coil therein.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a cross-sectional view illustrating a first embodiment of a plasma-enhanced thin-film-deposition equipment (PETFD equipment), according to the present disclosure.

FIG. 2 is a cross-sectional view illustrating a radio-frequency coil disposed to align with a reacting space of a chamber, according to a different embodiment of the present disclosure.

FIG. 3 is a cross-sectional view illustrating a second embodiment of the PETFD equipment, according to the present disclosure.

FIG. 4 is a cross-sectional view illustrating a third embodiment of the PETFD equipment, according to the present disclosure.

FIG. 5 is a cross-sectional view illustrating a fourth embodiment of the PETFD equipment, according to the present disclosure.

FIG. 6 is a cross-sectional view illustrating a fifth embodiment of the PETFD equipment, according to the present disclosure.

FIG. 7 is a cross-sectional view illustrating a sixth embodiment of the PETFD equipment, according to the present disclosure.

FIG. 8 is a cross-sectional view illustrating a seventh embodiment of the PETFD equipment, according to the present disclosure.

FIG. 9 is a cross-sectional view illustrating an eighth embodiment of the PETFD equipment, according to the present disclosure.

FIG. 10 is a perspective view illustrating a radio-frequency coil (RF coil) and an annular isolator of the PETFD equipment, according to the present disclosure.

FIG. 11 is a perspective view illustrating the RF coil and the annular isolator PETFD equipment, according to the present disclosure.

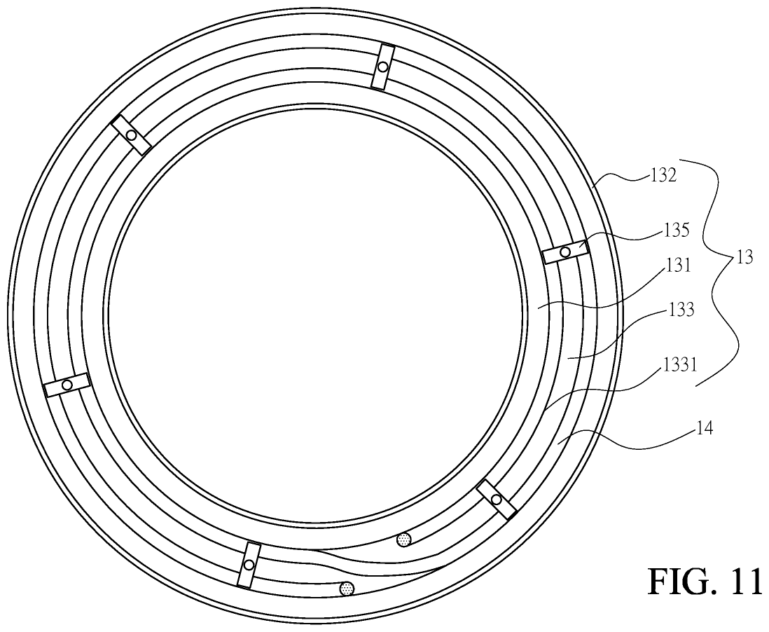

### DETAILED DESCRIPTION OF THE PREFERRED EMBODIMENTS

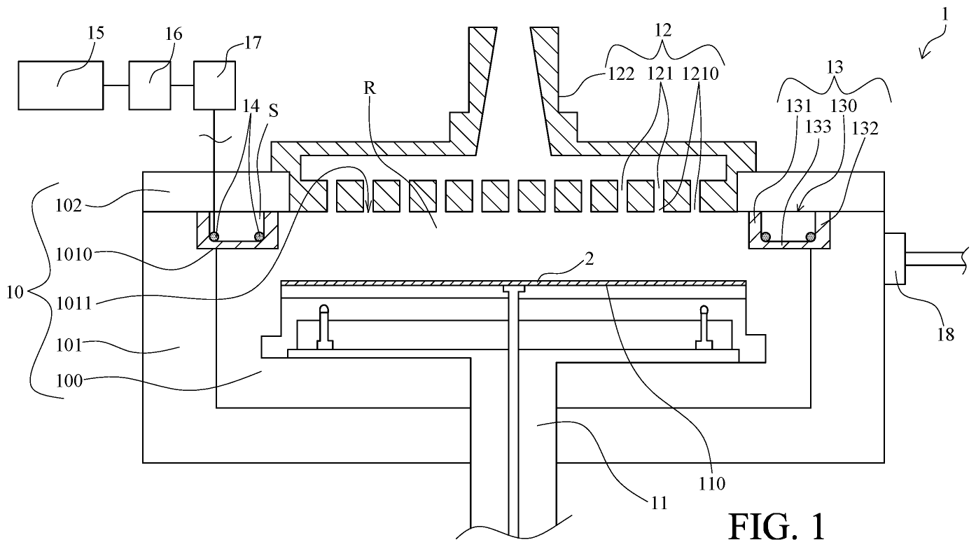

Referring to FIG. 1, which FIG. 1 is a cross-sectional view illustrating a first embodiment of a plasma-enhanced thin-film-deposition equipment, according to the present disclosure. As shown in FIG. 1, the plasma-enhanced thin-film-deposition equipment 1 (hereafter as “PETFD equipment 1”) includes a chamber 10, a carrier 11, a showerhead 12, an annular isolator 13 and a radio-frequency coil 14 (hereafter as “RF coil”).

The chamber 10 includes a containing space 100 containing a carrier 11. The carrier 11 is provided with a carrying surface 110 for carrying at least one substrate 2. The showerhead 12 is fluidly connected to the containing space 100. The showerhead 12 is provided with a plurality of gas-outlets 121 facing the carrying surface 110 of the carrier 11. The annular isolator 13 is provided with a mounting space S, and the RF coil 14 is disposed within the mounting space S. The RF coil 14 is also coupled to a radio-frequency power supply 15 (hereafter as “RF power supply 15”). In more detail, the carrier 11, the showerhead 12 and an annular isolator 13 together define a reacting space R within the containing space 100. The showerhead 12 is configured to distribute at least one precursor into the reacting space R, and moreover, the annular isolator 13 isolates the mounting space S from the containing space 100.

To be more specific, the showerhead 12 is disposed above the reacting space R, the carrier 11 is disposed beneath the reacting space R, and the annular isolator 13 is disposed to surround the reacting space R. On the other side, the RF coil 14 coupled to the RF power supply 15 is for ionizing the precursor (gas fluid) into plasma state, so as to assist, facilitate the ionized precursor (plasma) to deposit on and react with the substrate 2 on the carrying surface 110 in an effective and stable manner, and to grow and form an atomic-level thin film thereon. Also to mention that in an alternative operation, the showerhead 12 may be configured to distribute a cleaning gas, for cleaning the containing space 100 or the reacting space R.

In one embodiment, the annular isolator 13 isolates the mounting space S from the containing space 100. The annular isolator 13 is a ring made of ceramic, metal oxide (e.g. aluminum oxide) or metal nitride (e.g. aluminum nitride), moreover, the annular isolator 13 may be a ring formed integrally in one piece as single component.

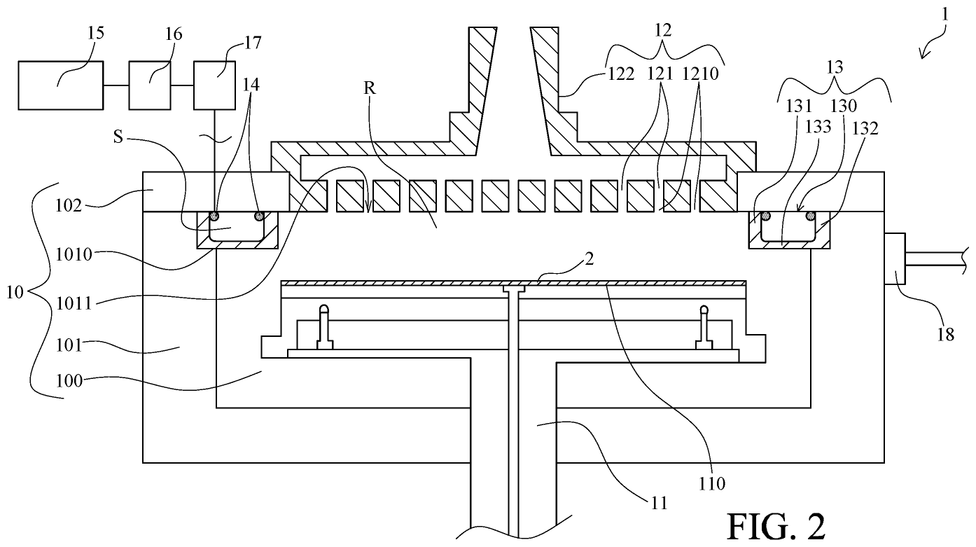

Generally, the reacting space R is a cylindrical space, wherein the RF coil 14 within the isolator 13 is positioned to surround any cross-section of the reacting space R. Preferably, the RF coil 14 is aligned with an upper edge of the reacting space R corresponding to exits 1210 of the gas-outlets 121, as shown in FIG. 2.

For example, the substrate 2 on the carrying surface 110 of the carrier 11 is a wafer, and the carrier 11 includes an electrode (e.g. electrode plate) and an insulator (e.g. insulating plate) and a heater disposed sequentially beneath the carrying surface 110. The electrode is connected to the carrying surface 110 in a direct or indirect manner. Furthermore, the electrode is coupled to a direct-current (DC) power supply or an RF power supply. Moreover, beside of distributing at least one precursor into the reacting space R, the showerhead 12 also distributes air, cleaning gas and/or other ionized gas (plasma), etc. The RF power supply 15 may be coupled to the RF coil 14, sequentially via a power meter 16 and a matching box 17.

In one embodiment, the chamber 10 includes a main body 101 and a lid cover 102. The main body 101 is a support portion 1010 and is provided with a chamber opening 1011 spatially connected to the containing space 100. The support portion 1010 protrudes from or concaves into the main body 101, for supporting the annular isolator 13. The lid cover 102 covers the chamber opening 1011 of the main body 101, so as to form the containing space 100 between the lid cover 102 and the main body 101.

Moreover, the annular isolator 13 includes an inner wall 131, an outer wall 132 and a bottom wall 133. The inner wall 131 surrounds the reacting space R, the outer wall 132 surrounds the inner wall 131, each of the inner wall 131 and the outer wall 132 includes one end connected to lid cover 102, and another end connected to the bottom wall 133. The bottom wall 133 is disposed on and supported by the support portion 1010 of the main body 101, wherein the inner wall 131 and the outer wall 132 and the bottom wall 133 together define the mounting space S.

As the lid cover 102 and the bottom wall 133 connect the inner wall 131 and the outer wall 132 from two sides (upside and downside of FIG. 1 and FIG. 2), the PETFD equipment 1 is provided with the mounting space S completely isolated from the containing space 100 (no spatial or fluid connection therebetween) by the annular isolator 13, thereby to prevent the precursor or other gas fluid from depositing into any gap or space between the annular isolator 13 and the containing space 100 (interconnecting the mounting space S and the reacting space R), and further to prevent the deposition from causing electric arc during the deposition process.

Apparently, with the annular isolator 13 made of ceramic or metal oxide or metal nitride and formed as one single piece, the annular isolator 13 itself has no tiny gap or space formed by assembled parts, and no tiny gap or space on surface(s) at side of the containing space 100 (or the reacting space R), thereby to prevent the undesired deposition within the tiny gap or space from causing the electric arc. Also to mention, the undesired deposition on the surface(s) of the annular isolator 13 can be easily removed, via a cleaning process.

In more detail, the lid cover 102 of the chamber 10 may be provided with other opening(s), for mounting the showerhead 12, gas pipelines, sensors or other equipment(s) into the containing space 100. For example, the showerhead 12 may be disposed deeply within the containing space 100 from outside and include a gas-inlet pipeline 122 extending through and mounted on the other opening. In the other hand, the main body 101 may also be provided with other opening(s), for mounting other gas pipelines, sensors, optical-emission-spectroscopy port 18 (OES port) or other equipment(s) into the containing space 100 from the outside, wherein the OES port 18 is disposed at a lateral side of the main body 101 corresponding to the substrate 2. The lid cover 102 is directly connected to and/or pressed on the one ends of the inner wall 131 and the outer wall 132. Furthermore, a sealing member (e.g. O-ring) may be disposed on the one ends of the inner wall 131 and the outer wall 132 or on the lid cover 102, and be squeezed, compressed between the walls 131, 132 and the lid cover 102.

Specifically, as shown in FIG. 1, the main body 101 has a certain thickness, and is provided with an annular cavity as the support portion 1010 for supporting the annular isolator 13. The support portion 1010 may fully or partially contact to support the bottom wall 133 of the annular isolator 13. Furthermore, the chamber 10 has the lid cover 102 connected to the annular isolator 13 by the inner wall 131 and the outer wall 132, and has the support portion 1010 of the main body 10 connected to the annular isolator 13 by the bottom wall 133, so as to partially or entirely contain and lock the annular isolator 13 between the lid cover 102 and the support portion 1010. Also, the lid cover 102, the inner wall 131 and the outer wall 132 and the bottom wall 133 together define the mounting space S therebetween.

In another preferable embodiment, in comparison with the aforementioned embodiments, the main body 101 includes a lateral portion (at the lateral side) thereof bending toward the outer wall 132 of the annular isolator 13 and outward, thereby to form the support portion 1010 in a manner of protruding out of the main body 101. Likewise, the support portion 1010 in this embodiment partially or entirely support the bottom wall 133 of the annular isolator 13, and the lid cover 102 is connected to and covers the one ends of the inner wall 131 and the outer wall 132. The bottom wall 133 interconnects to the another end of the inner wall 131 and the another end of the outer wall 132, therefore the annular isolator 13 is entirely or partially held and locked between the support portion 1010 of the main body 101 and the lid cover 102. Furthermore, the lid cover 102, the inner wall 131 and the outer wall 132 and the bottom wall 133 together define the mounting space S. It should be noted, although the support portion 1010 in the embodiments of FIG. 2 to FIG. 6 is similar to that in the embodiment of FIG. 1, however other different configuration(s) of the support portion may also be arranged with the embodiments of FIG. 2 to FIG. 6.

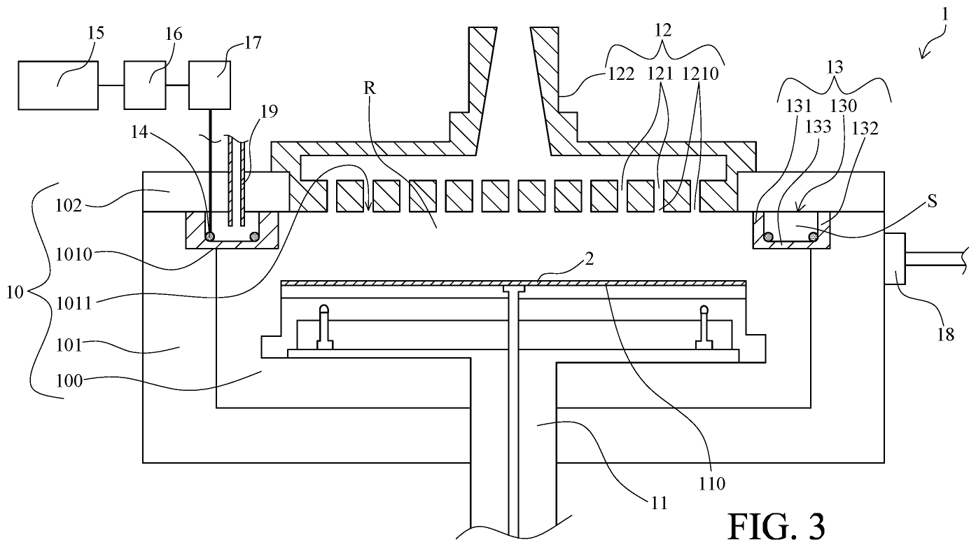

Referring to FIG. 3, which is a cross-sectional view illustrating a second embodiment of the plasma-enhanced thin-film-deposition, according to the present disclosure. The second embodiment is different from the aforementioned first embodiment in that the PETFD equipment 1 further includes at least one gas-inlet pipeline 19 that passes through the lid cover 102 and extends into the mounting space S of the annular isolator 13. The gas-inlet pipeline 19 is configured to transfer a gas fluid (e.g. nitrogen, etc.) into the mounting space S of the annular isolator 13. Furthermore, the gas-inlet pipeline 19 may be disposed with at least one valve, for controlling flow rate of the gas fluid.

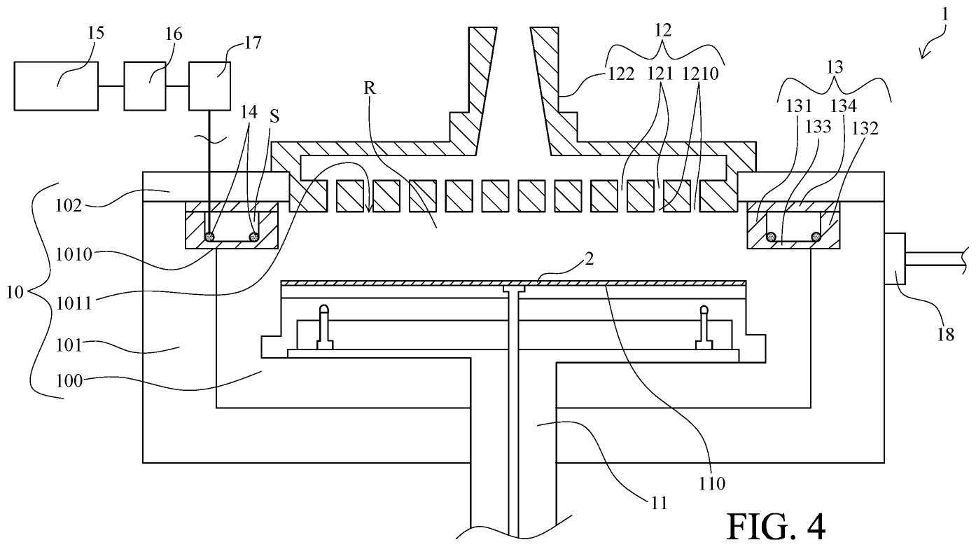

Referring to FIG. 4, which is a cross-sectional view illustrating a third embodiment of the plasma-enhanced thin-film-deposition, according to the present disclosure. The third embodiment is different from the aforementioned first embodiment in that the annular isolator 13 further includes a sealing cover 134. The sealing cover 134 interconnects the one ends of the inner wall 131 and the outer wall 132, and the sealing cover 134, the inner wall 131 and the outer wall 132 and the bottom wall 133 together define the mounting space S. With such configuration, the lid cover 102 interconnects and/or presses on the other ends of the inner wall 131 and the outer wall 132, via the sealing cover 134. Furthermore, a sealing member (e.g. O-ring) may be disposed between the one ends of the walls 131, 132 and the sealing cover 134, in a manner of being squeezed and compressed therebetween.

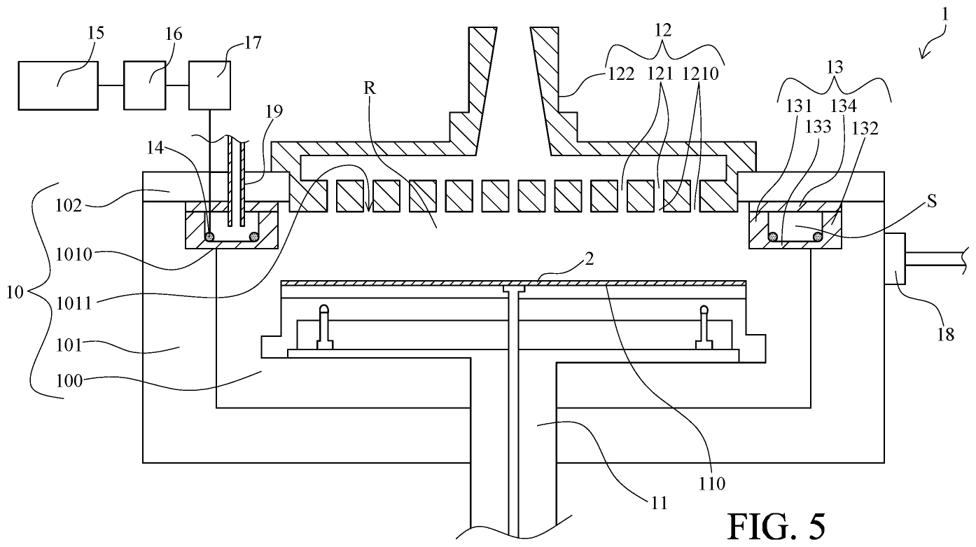

Referring to FIG. 5, which is a cross-sectional view illustrating a fourth embodiment of the plasma-enhanced thin-film-deposition, according to the present disclosure. The fourth embodiment is different from the aforementioned third embodiment in that the PETFD equipment 1 further includes the aforementioned gas-inlet 19 which passes through the sealing cover 134 (also through the lid cover 102) into the mounting space S of the annular isolator 13, and which is configured to transfer the gas fluid (e.g. nitrogen, etc.) into the mounting space S. Also, similar to the second embodiment, the gas-inlet 19 may also be disposed with at least one valve.

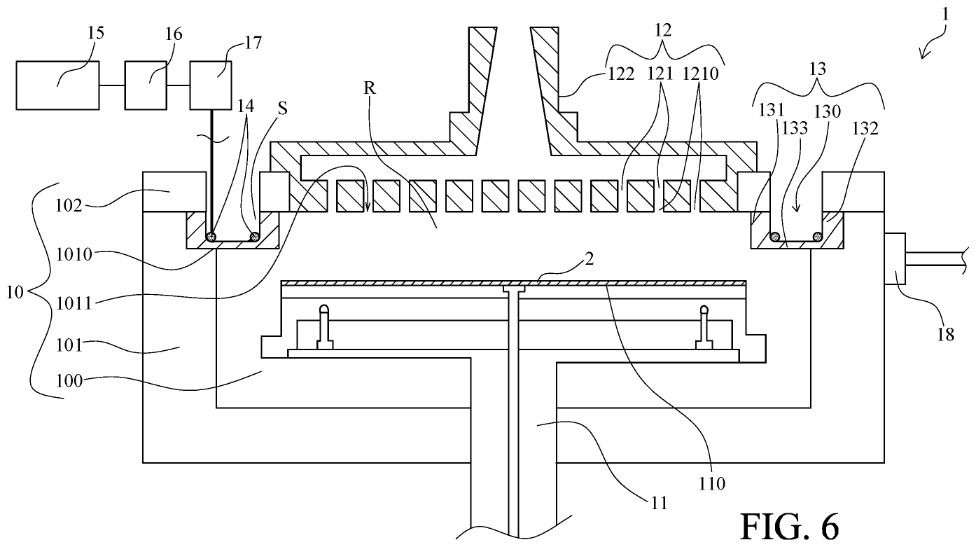

Referring to FIG. 6, which is a cross-sectional view illustrating a fifth embodiment of the plasma-enhanced thin-film-deposition, according to the present disclosure. The fifth embodiment is different from the aforementioned third embodiment in that the annular isolator 13 includes an annular opening 130. The mounting space S is fluidly connected to the outside environment. Therewith, the lid cover 102 is also provided with a hollow portion, in correspondence to at least a portion of the annular opening 130, thereby the mounting space S is fluidly connected to the outside environment sequentially via the annular opening 130 and the hollow portion.

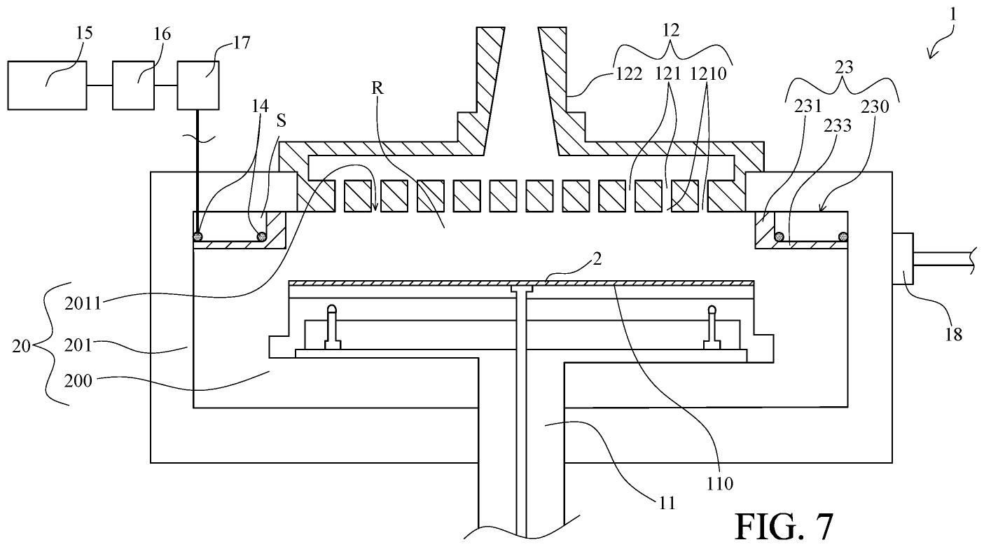

Referring to FIG. 7, which is a cross-sectional view illustrating a sixth embodiment of the plasma-enhanced thin-film-deposition, according to the present disclosure. The sixth embodiment is different from the aforementioned first embodiment in that the annular isolator 23 in this embodiment is configured to include only the inner wall 231 and the bottom wall 233 (with the outer wall 132 omitted). Also to mention, the chamber 20 in this embodiment has no support portion 1010 and lid cover 102 (refer to FIG. 1) for holding the annular isolator 23, but to directly connect to the inner wall 231 and the bottom wall 233 thereof.

To be specific, the inner wall 231 is disposed to surround the reacting space R and is connected to the chamber 20, and the bottom wall 233 interconnects the inner wall 231 and the main body 201 of the chamber 20, and the bottom wall 233, the inner wall 231 and the main body 201 together define the mounting space S therebetween. In this embodiment, within the containing space 200, the main body 201 of the chamber 20 includes the lateral portion connected to the bottom wall 233 of the annular isolator 23, and is further provided with a ceiling portion connected to the inner wall 231 of the annular isolator 23, instead of the lid cover 102 in aforementioned embodiment, so as to define and divide the containing space 200 into the mounting space S and the reacting space R. By virtue of the chamber 20 which is directly connected to the inner wall 231 and the bottom wall 233 of the annular isolator 23, the PETFD equipment 1 in this embodiment can effectively prevent the gas fluid deposited between the main body 201 and the annular isolator 23, so as to prevent the deposition from causing the undesired electric arc, during the deposition process. Moreover, with the annular isolator 23 made of ceramic or metal oxide or metal nitride and also formed as one single piece, the annular isolator 23 itself has no tiny gap or space formed by assembled parts, also no tiny gap or space on surface(s) at side of the reacting space R, thereby to prevent the undesired deposition within the tiny gap or space from causing the electric arc. Also, the undesired deposition on the surface(s) of the annular isolator 23 can be easily removed, via a cleaning process.

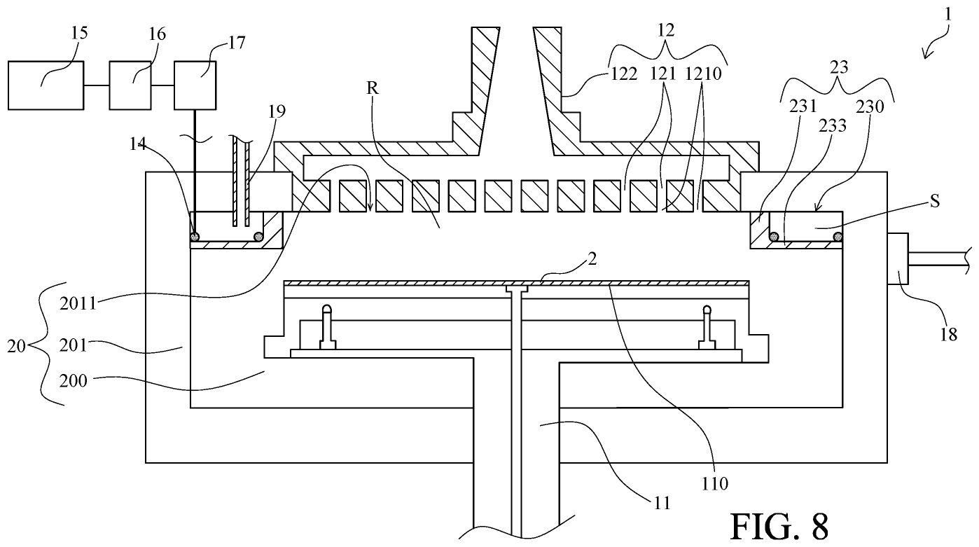

Referring to FIG. 8, which is a cross-sectional view illustrating a seventh embodiment of the plasma-enhanced thin-film-deposition, according to the present disclosure. The seventh embodiment is different from the aforementioned first embodiment in that the PETFD equipment 1 further include the aforementioned gas-inlet pipeline 19 which passes through the main body 201 of the chamber 20 and into the mounting space S of the annular isolator 23, for transferring gas fluid (e.g. nitrogen) into the mounting space S. Similar to the aforementioned embodiments, the gas-inlet pipeline 19 may be disposed with at least one valve.

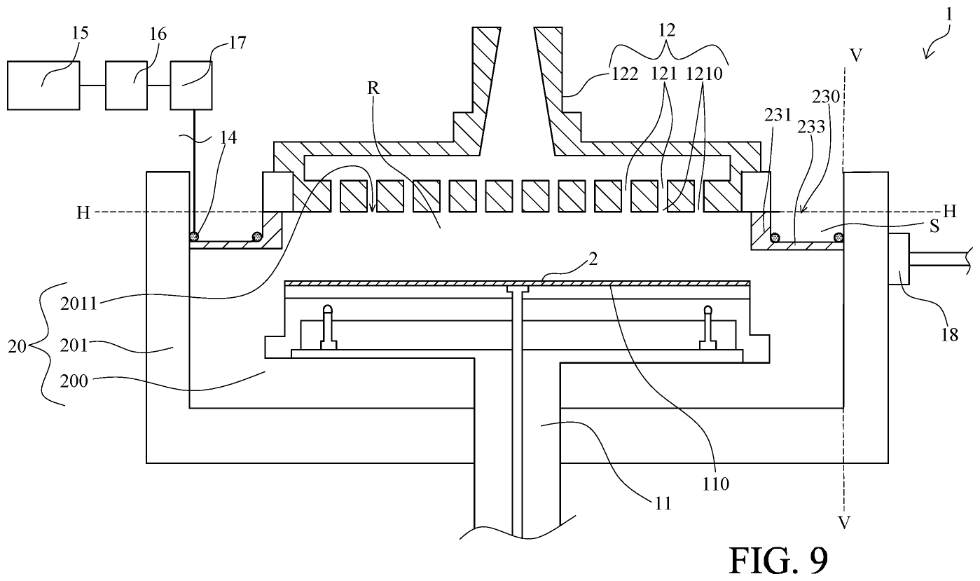

Referring to FIG. 9, which is a cross-sectional view illustrating an eighth embodiment of the plasma-enhanced thin-film-deposition, according to the present disclosure. The eighth embodiment is different from the aforementioned sixth embodiment in that the annular isolator 23 is provided with an annular opening 230, and the mounting space S is fluidly connected to the outside environment via the annular opening 230. In correspondence with at least a portion of the annular opening 230, the main body 201 of the chamber 20 is provided with a hollow portion which extends upward from a visual horizontal plane H (where the inner wall 231 of the annular isolator 23 and the ceiling portion of the main body 201 are connected), and through the ceiling portion of main body 201. The mounting space S is fluidly connected to the outside environment sequentially via the annular opening 230 and the hollow portion of the main body 201. To be more specific, the hollow portion is proximately a hole opened on the ceiling portion of the main body 201, and therefore the ceiling portion still partially interconnects the inner wall 231 of the annular isolator 23 and the lateral portion thereof.

In alternative embodiment, the hollow portion may be formed in a horizontal manner, in which the hollow portion extends from another visual plane V (where the bottom wall 233 and the lateral portion of main body 201 are connected) and through the main body 201, and the mounting space S is fluidly connected to the outside environment sequentially via the opening 230 and the hollow portion. Similar as aforementioned, the hollow portion is proximately a hole opened on the lateral portion of the main body 201, and therefore the lateral portion still partially interconnects the bottom wall 233 of the annular isolator 23 and the ceiling portion thereof.

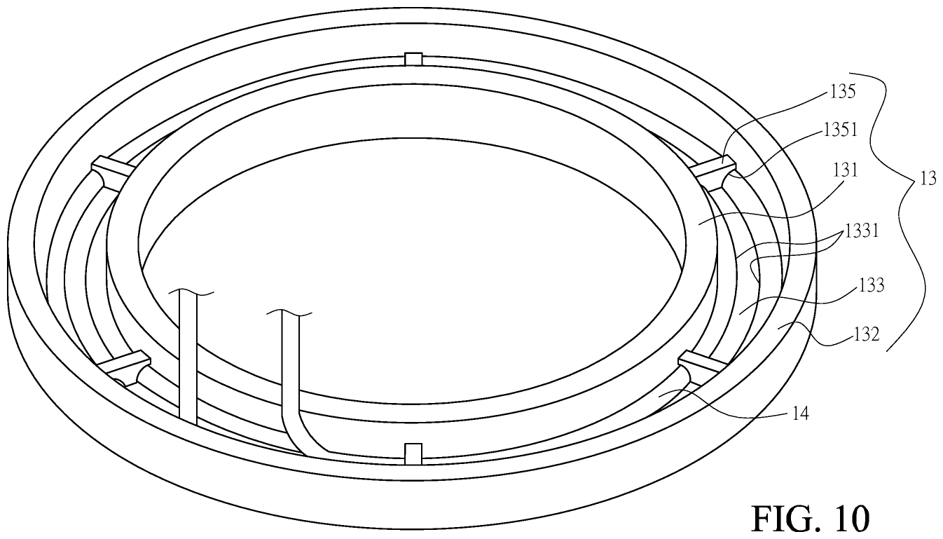

In a more detail embodiment as shown in FIG. 9 and FIG. 10, which are a perspective view and a top view of the RF coil 14 and the annular isolator 13. The bottom wall 133 of the annular isolator 13 is provided with a groove slot 1331 for mounting the RF coil 14 on the bottom wall 133, wherein the RF coil 14 is partially contained and positioned within the groove slot 1331. Moreover, the annular isolator 13 may be disposed with at least one of fastener 134 (plural in this embodiment) on the bottom wall 133, for fastening and locking the RF coil 14 on the bottom wall 133 and/or into the groove slot 1331. Furthermore, the fastener 134 may be provided with a concave portion 1341, for partially containing and holding the RF coil 14.

It should be noted that the bottom wall 233 of the annular isolator 23 may be provided with a groove slot 1331 for mounting and positioning the RF coil 14, and may further combine with the fastener 134 to further fasten and lock the RF coil 14 thereon, in a manner similar to the abovementioned embodiment.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

We claim:

1. A plasma-enhanced thin-film-deposition equipment, comprising:
a chamber including a containing space;
a carrier disposed within the containing space and provided with a carrying surface for carrying at least one substrate;
a showerhead fluidly connected to the containing space; wherein the showerhead is provided with a plurality of gas-outlets facing the carrying surface of the carrier;
an annular isolator provided with a mounting space, wherein the carrier and the showerhead and the annular isolator together define a reacting space within the containing space, and the mounting space is isolated from the containing space, and the showerhead is configured to distribute at least one precursor into the reacting space; and
a radio-frequency coil disposed within the mounting space of the annular isolator and coupled to a radio-frequency power supply.

2. The plasma-enhanced thin-film-deposition equipment according to claim 1, wherein the chamber includes:
a main body including a support portion and provided with a chamber opening; wherein the chamber opening is spatially connected to the containing space, and wherein the support portion protrudes from or concave into the main body for supporting the annular isolator; and
a lid cover covering the chamber opening of the main body to form the containing space between the main body and the lid cover.

3. The plasma-enhanced thin-film-deposition equipment according to claim 2, wherein the annular isolator includes:
an inner wall disposed to surround the reacting space;
an outer wall disposed to surround the inner wall; wherein each of the inner wall and the outer wall has one end connected to the lid cover of the chamber; and
a bottom wall disposed on the support portion of the main body of the chamber to interconnect another end of the inner wall and another end of the outer wall; wherein the lid cover, the inner wall, the outer wall and the bottom wall together define the mounting space therebetween.

4. The plasma-enhanced thin-film-deposition equipment according to claim 3, further comprising at least one gas-inlet pipeline passing through the lid cover into the mounting space of the annular isolator, for transferring a gas fluid into the mounting space.

5. The plasma-enhanced thin-film-deposition equipment according to claim 3, further comprising a sealing member disposed between the annular isolator and the lid cover, and connected to the one ends of the inner wall and the outer wall.

6. The plasma-enhanced thin-film-deposition equipment according to claim 3, wherein the inner wall, the outer wall and the bottom wall are formed monolithically.

7. The plasma-enhanced thin-film-deposition equipment according to claim 2, wherein the annular isolator includes:
an inner wall disposed to surround the reacting space;
an outer wall disposed to surround the inner wall;
a bottom wall disposed on the support portion of the main body to interconnect one end of the inner wall and one end the outer wall; and
a sealing cover connected another end of the inner wall and another end of the outer wall; wherein the sealing cover, the inner wall, the outer wall and the bottom wall together define the mounting space.

8. The plasma-enhanced thin-film-deposition equipment according to claim 7, further comprising at least one gas-inlet pipeline passing through the sealing cover and the mounting space of the annular isolator, for transferring a gas fluid into the mounting space.

9. The plasma-enhanced thin-film-deposition equipment according to claim 7, wherein the bottom wall of the annular isolator is provided with a groove slot for positioning the radio-frequency coil.

10. The plasma-enhanced thin-film-deposition equipment according to claim 7, wherein a fastener is disposed on the bottom wall of the annular isolator, for fastening the radio-frequency coil on the bottom wall.

11. The plasma-enhanced thin-film-deposition equipment according to claim 7, wherein the inner wall, the outer wall and the bottom wall formed are formed monolithically.

12. The plasma-enhanced thin-film-deposition equipment according to claim 2, wherein the annular isolator is provided with an annular opening, wherein the mounting space is fluidly connected to an outside environment via the annular opening.

13. The plasma-enhanced thin-film-deposition equipment according to claim 1, further comprising an optical-emission-spectroscopy port that is disposed on a lateral side of the main body, corresponding to the carrying surface of the carrier.

14. The plasma-enhanced thin-film-deposition equipment according to claim 1, wherein the annular isolator includes:
an inner wall disposed to surround the reacting space and connected to the chamber; and
a bottom wall interconnecting the inner wall and the chamber, wherein the bottom wall, the inner wall and the chamber together define the mounting space therebetween.

15. The plasma-enhanced thin-film-deposition equipment according to claim 14, further comprising at least one gas-inlet pipeline passing through the sealing cover and the mounting space of the annular isolator, for transferring a gas fluid into the mounting space.

16. The plasma-enhanced thin-film-deposition equipment according to claim 14, wherein the annular isolator is provided with an annular opening, wherein the mounting space is fluidly connected to an outside environment via the annular opening.

17. The plasma-enhanced thin-film-deposition equipment according to claim 1, wherein the annular isolator is formed as one piece.

18. The plasma-enhanced thin-film-deposition equipment according to claim 1, wherein the annular isolator is a ring and made of ceramic, metal oxide or metal nitride.

19. The plasma-enhanced thin-film-deposition equipment according to claim 1, wherein the radio-frequency coil is coupled to the radio-frequency power supply sequentially via a power meter and a matching box.

20. The plasma-enhanced thin-film-deposition equipment according to claim 1, wherein the radio-frequency coil is disposed to align with an upper edge of the reacting space.
